(19) United States
(12) Patent Application Publication
(10) Pub. No.: US 2023/0246008 A1
(43) Pub. Date: Aug. 3, 2023

(54) PASSIVE DEVICE STRUCTURE OF SEMICONDUCTOR PACKAGE AND METHOD FOR MANUFACTURING THE SAME

(71) Applicant: Elohim Incorporation, Daejeon (KR)

(72) Inventors: Dong-Ki LEE, Gyeonggi-do (KR); Taedong KIM, Gyeonggi-do (KR); Seunggu LIM, Gyeonggi-do (KR); Jihoon CHA, Gyeonggi-do (KR); Yeonglyeol PARK, Gyeonggi-do (KR)

(21) Appl. No.: 17/671,939

(22) Filed: Feb. 15, 2022

(30) Foreign Application Priority Data
Jan. 28, 2022 (KR) 10-2022-0013043

(51) Int. Cl. H01L 25/16; H01L 23/498

(52) U.S. Cl. CPC H01L 25/16; H01L 23/49816; H01L 24/73

(57) ABSTRACT

Disclosed are a passive device structure of a semiconductor package and a method for manufacturing the same to prevent an integrated passive device (IPD) positioned between ball grid arrays for connecting a substrate and a printed circuit board from being damaged by the ball grid arrays or to prevent a decrease in operation performance.

### CROSS-REFERENCE TO RELATED APPLICATION

This present application claims the benefit of priority to Korean Patent Application No. 10-2022-0013043, entitled “SEMICONDUCTOR PACKAGE AND METHOD FOR MANUFACTURING THE SAME,” filed on Jan. 28, 2022, in the Korean Intellectual Property Office, the entire disclosure of which is incorporated herein by reference.

### FIELD

The present disclosure relates to a passive device structure of a semiconductor package and a method for manufacturing the same, and more particularly, to a passive device structure of a semiconductor package and a method for manufacturing the same to prevent an integrated passive device (IPD) positioned between ball grid arrays for connecting a substrate and a printed circuit board or a ball grid array from being damaged due to a difference in an occupied space or prevent operation performance from being reduced. The present invention resulted from “Ultra-small, high-capacity smart passive device for 5G Mobile” of “Initial Startup Package” supported by the Ministry of SMEs and Startups (Project No.: 10429536).

### BACKGROUND

The following description is only for the purpose of providing background information related to embodiments of the present disclosure, and the contents to be described do not necessarily constitute related art.

Recently, the development direction of next-generation semiconductors has changed from a system on chip (SOC) to a system in package (SIP), and accordingly, a structure of a passive device has been also downsized according to aspects. An integrated passive device (IPD) is a semiconductor package structure developed to meet these requirements, and is generally positioned between ball grid arrays for electrical connection of a substrate and a printed circuit board.

Such an integrated passive device may greatly minimize the size of the semiconductor package compared to a conventional passive device structure mounted around a main computing chip on the substrate or on the printed circuit board, and is disposed at a place where electrical signals are moved to pursue stabilization of electrical signals and maximization of energy efficiency.

Meanwhile, in the semiconductor package process, an underfill process may be performed as a process in which a fluid material forming an underfill is filled by a capillary phenomenon. At this time, since a space occupied by the integrated passive device of the semiconductor package is wide, a flow rate of the fluid material may be changed, and as a result, there is a problem that the ball grid array near the space where the integrated passive device is mounted may be broken or the integrated passive device may be damaged.

In addition, since the integrated passive device is surrounded by an underfill material in the semiconductor packaging process, thermal flow is difficult, and as a result, there is a problem that the device is broken by stress due to heat or there is a risk of reduced operation performance due to high temperature.

Accordingly, there is a need for a structure of an integrated passive device capable of reducing damage to the ball grid array of the semiconductor package and reducing thermal stress.

The background art described above may be technical information retained by the present inventors in order to derive the present disclosure or acquired by the present inventors along the process of deriving the present disclosure, and thus is not necessarily a known art disclosed to the general public before the filing of the present disclosure.

### SUMMARY

An object of the present disclosure is to provide a passive device structure of a semiconductor package and a method for manufacturing the same so as to be electrically in contact with a substrate or/and a chip of a patterned semiconductor package by forming via holes inside an integrated passive device and forming bumps on one surface of the integrated passive device.

Further, another object of the present disclosure is to provide a passive device structure of a semiconductor package and a method for manufacturing the same capable of preventing damage to ball grid arrays near a space in which an integrated passive device is mounted according to a change in flow rate by a fluid material forming an underfill of an underfill process in a semiconductor package process.

Further, yet another object of the present disclosure is to provide a passive device structure of a semiconductor package and a method for manufacturing the same to minimize an integrated passive device surrounded by an underfill material from being broken by stress due to heat or the operation performance due to high temperature.

The aspect of the present disclosure is not limited to the above-mentioned aspects, and other aspects and advantages of the present disclosure, which are not mentioned, will be understood through the following description, and will become apparent from the embodiments of the present disclosure. In addition, it will be appreciated that the aspects and advantages of the present disclosure will be easily realized by those skilled in the art based on the appended claims and a combination thereof.

According to an aspect of the present disclosure, a passive device structure of a semiconductor package may include a substrate mounted on a printed circuit board; a main computing chip mounted on the substrate; and a passive device structure which is provided in an adhesive layer formed between the printed circuit board and the substrate and includes an integrated passive device (IPD) electrically connecting the printed circuit board and the substrate.

At this time, the passive device structure may include at least one via hole penetrating into the integrated passive device, at least one first bump which is formed on one surface facing the substrate of the integrated passive device and in contact with a first through hole of the via hole penetrating through the integrated passive device, and at least one second bump formed on the other surface facing the printed circuit board of the integrated passive device.

In the embodiment of the present disclosure, the first bumps may be aligned in a direction parallel to the formation direction of the integrated passive device on one surface facing the printed circuit board of the integrated passive device.

In the embodiment of the present disclosure, the second bump may be in contact with a second through hole of the via hole penetrating through the integrated passive device.

In the embodiment of the present disclosure, the second bumps may be aligned in a direction parallel to the formation direction of the integrated passive device on the other surface facing the substrate of the integrated passive device.

In the embodiment of the present disclosure, the sizes of the first bump and the second bump may be different from each other.

In the embodiment of the present disclosure, a diameter of the second bump may be larger than the diameter of the first bump.

In the embodiment of the present disclosure, the passive device structure of the semiconductor package may further include a ball grid array (B GA) disposed between the printed circuit board and the substrate, in which the thickness of the passive device structure may be formed to be equal to or smaller than the ball grid array.

According to another aspect of the present disclosure, a method for manufacturing a passive device of a semiconductor package may be performed by mounting a substrate on a printed circuit board, forming a passive device structure including an integrated passive device (IPD) electrically connecting the printed circuit board and the substrate, and mounting a main computing chip on the substrate.

Meanwhile, the process of forming the passive device structure may be performed by forming at least one via hole penetrating into the integrated passive device, forming at least one first bump which is formed on one surface facing the printed circuit board of the integrated passive device and in contact with a first through hole of the via hole penetrating through the integrated passive device, and forming at least one second bump formed on the other surface facing the substrate of the integrated passive device.

Other aspects, features, and advantages than those described above will become apparent from the following drawings, claims, and detailed description of the present disclosure.

According to the embodiment of the present disclosure, the integrated passive device is provided in the semiconductor package to greatly minimize the size of the semiconductor package compared to a conventional passive device structure mounted around a main computing chip on the substrate or on the printed circuit board, and the integrated passive device is disposed at a place where electrical signals are moved to pursue stabilization of electrical signals and maximization of energy efficiency.

In addition, the integrated passive device may maintain electrical connection with the substrate and/or the main computing chip through the passive device structure in which the bumps are formed between the substrate of the semiconductor package and the main computing chip.

Specifically, the underfill process of the semiconductor package may be performed by filling the fluid material forming the underfill in the space between the substrate and the main computing chip by using a capillary phenomenon. At this time, the integrated passive device maintains the electrical connection between the main computing chip and the substrate by the first bumps formed between the main computing chip and the integrated passive device and the second bumps formed between the substrate and the integrated passive device, thereby preventing the ball grid array in the space where the integrated passive device is mounted from being damaged by the flow of the fluid material forming the underfill.

Further, although the periphery of the integrated passive device is surrounded by the fluid material forming the underfill, thermal flow is enabled by the first bumps formed between the main computing chip and the integrated passive device and the second bumps formed between the substrate and the integrated passive device, thereby preventing the damage to the integrated passive device due to stress by the heat and a decrease in operation performance due to high temperature.

The effects of the present disclosure are not limited to those mentioned above, and other effects not mentioned can be clearly understood by those skilled in the art from the following description.

### BRIEF DESCRIPTION OF THE DRAWINGS

The above and other aspects, features, and advantages of the present disclosure will become apparent from the detailed description of the following aspects in conjunction with the accompanying drawings, in which:

FIG. 1 is a diagram illustrating a semiconductor package including a passive device structure according to an embodiment of the present disclosure;

FIG. 2 is a diagram illustrating the passive device structure of FIG. 1;

FIG. 3 is a diagram illustrating a structure of the passive device structure of the present disclosure and a ball grid array;

FIG. 4 is a diagram illustrating a first modification embodiment of the passive device structure of the present disclosure;

FIG. 5 is a diagram illustrating a second modification embodiment of the passive device structure of the present disclosure;

FIG. 6 is a diagram illustrating a third modification embodiment of the passive device structure of the present disclosure; and

FIGS. 7 and 8 are flowcharts illustrating processes of semiconductor package according to an embodiment of the present disclosure.

### DETAILED DESCRIPTION

Hereinafter, exemplary embodiments disclosed in this specification will be described in detail with reference to the accompanying drawings and the same or similar components are denoted by the same reference numerals regardless of a sign of the drawing, and duplicated description thereof will be omitted. Suffixes “module” and “unit” for components used in the following description are given or mixed in consideration of easy preparation of the specification only and do not have their own distinguished meanings or roles. Further, in describing the exemplary embodiment of this specification, a detailed description of related known technologies will be omitted if it is determined that the detailed description makes the gist of the exemplary embodiment disclosed in this specification unclear. Further, it is to be understood that the accompanying drawings are just used for easily understanding the exemplary embodiments disclosed in the present disclosure and a technical spirit disclosed in the present disclosure is not limited by the accompanying drawings and all changes, equivalents, or substitutes included in the spirit and the technical scope of the present disclosure are included.

Terms including an ordinal number, such as first, second, etc., may be used for describing various constituent elements, but the constituent elements are not limited by the terms. The terms are used only to discriminate one constituent element from another constituent element.

It should be understood that, when it is described that a component is “coupled” or “connected” to the other component, the component may be directly coupled or connected with the other component, but there may be another component therebetween. In contrast, it should be understood that, when it is described that a component is “directly coupled” or “directly connected” to the other component, it should be understood that no component is present therebetween.

Singular expressions used herein include plurals expressions unless they have definitely opposite meanings in the context.

The terms “comprising” and “having” specify the presence of stated features, integers, steps, operations, elements, components or combinations thereof, but do not preclude the presence or addition of one or more other features, integers, steps, operations, elements, components, or combinations thereof in advance.

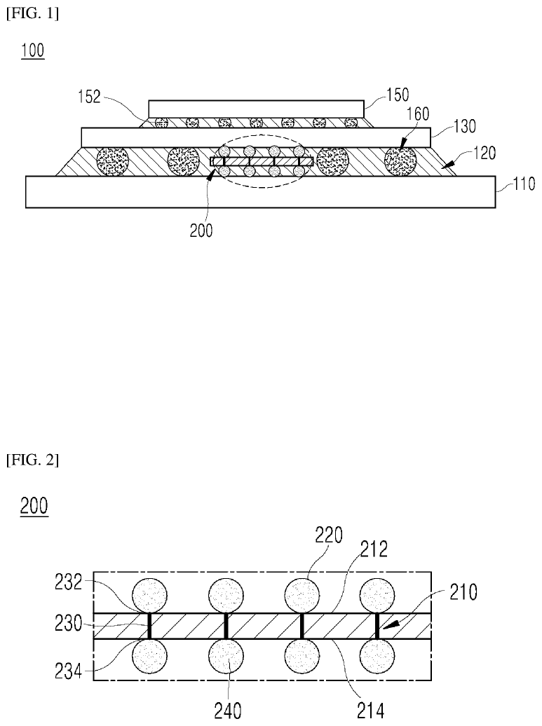

FIG. 1 is a diagram illustrating a semiconductor package including a passive device structure according to an embodiment of the present disclosure.

Referring to the drawing, a semiconductor package 100 according to an embodiment of the present disclosure may include a printed circuit board 110, a substrate 130, a main computing board 150, a passive device structure 200, and the like.

The printed circuit board 110 may include a plurality of external bumps, and substrate wirings and internal bumps capable of electrically connecting the semiconductor package. In addition, the substrate 130 to be described below may be mounted on the printed circuit board 110, and an adhesive layer 120 formed by an underfill process may be formed in a space between the printed circuit board 110 and the substrate 130.

The substrate 130 may be formed with a plurality of wirings that may be electrically connected with the printed circuit board 110. In addition, in the space between the printed circuit board 110 and the substrate 130, the adhesive layer 120 formed by the underfill process may be formed with ball grid arrays 160 that electrically connect the substrate 130 and the printed circuit board 110.

The ball grid array 160 is a packaging method that minimizes a problem of increasing the size of the semiconductor when the number of pins of the integrated circuit increases. If the number of pins of the integrated circuit increases, soldering pastes may be connected with each other in a soldering process so that the circuit may be short-circuited, but the ball grid array may prevent the short-circuit of the circuit because a correct amount of soldering is enabled.

While the ball grid array 160 is formed between the substrate 130 and the printed circuit board 110, the thermal conductivity between the printed circuit board 110 and the substrate 130 may increase, and accordingly, heat generated inside the integrated circuit may be discharged to the printed circuit board 110.

Referring back to the drawing, the ball grid array 160 may be formed in a size equal to the size of the space between the printed circuit board 110 and the substrate 130. That is, the ball grid array 160 may be formed between the printed circuit board 110 and the substrate 130 to have a width equal to or similar to the width of the adhesive layer 120 so as to support the printed circuit board 110 and the substrate 130.

The main computing chip 150 may be mounted on the upper side of the substrate 130, and may include a plurality of connection terminals 152 that may be electrically connected with the substrate 130. The connection terminals 152 may be formed in a size corresponding to the space between the substrate 130 and the main computing chip 150, and may be disposed in an array in a shape corresponding to the ball grid array 160 described above.

Meanwhile, the passive device structure 200 may be installed in a space in which the adhesive layer 120 is formed between the substrate 130 and the printed circuit board 110. The passive device structure 200 is a configuration for electrical connection between the substrate 130 and the printed circuit board 110.

Such a passive device structure 200 may be positioned at a place where the electric signal is moved to stabilize an electric signal, thereby contributing to maximizing energy efficiency.

The adhesive layer 120 in which the passive device structure 200 is positioned may be filled with a fluid material for forming an underfill by a capillary phenomenon. While the fluid material is filled in the adhesive layer 120, the fluid material collides with the passive device structure 200 and the flow rate of the fluid material may be changed. The ball grid array 160 of the adhesive layer 120 may be changed or broken according to the changing flow rate of the fluid material.

To this end, bumps may be formed between an integrated passive device 210 of the passive device structure 200 and the substrate 130 and between the integrated passive device 210 and the printed circuit board 110. That is, the bumps on the upper and lower sides of the integrated passive device 210 are fixed to the substrate 130 and the printed circuit board 110, and a space occupied by the integrated passive device 210 may be fabricated to be equal to or similar to the space occupied by the ball grid array 160. As a result, even if the fluid material is introduced into the adhesive layer 120, the space occupied by the integrated passive device 210 is uniformized with the ball grid array to minimize the occurrence of stress by a change in fluid flow or the occurrence of stress by a difference in coefficient of thermal expansion of the adhesive layer during driving after completing the formation of the underfill, thereby preventing the ball grid array 160 from being broken.

As such, the structure of the integrated passive device 210 for preventing the breakage of the ball grid array 160 will be described in detail with reference to the following drawings.

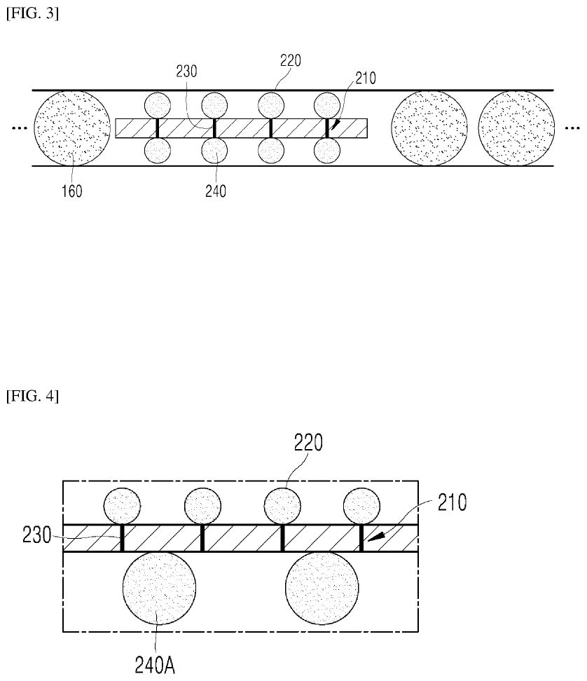

FIG. 2 is a diagram illustrating the passive device structure of FIG. 1 and FIG. 3 is a diagram illustrating a structure of the passive device structure of the present disclosure and the ball grid array.

Before the description of the drawings, the passive device structure 200 including an integrated passive device (IPD) such as a condenser, a resistor, and an inductor may be positioned in the adhesive layer 120 (see FIG. 1).

The passive device structure 200 may include an integrated passive device 210 formed with via holes 230, first bumps 220, and second bumps 240.

The integrated passive device 210 may be an integrated circuit for amplifying power by simultaneously using a power amplifying device and a passive device such as a resistor, a capacitor, and an inductor on a semiconductor substrate.

The passive device structure 200 including such an integrated passive device 210 may include at least one via hole 230, first bump 220, and second bump 240.

Specifically, the via hole 230 may be formed to penetrate from one surface 212 of the integrated passive device 210 facing the substrate 130 to the other surface 214 facing the printed circuit board 110. That is, a first through hole 232 formed in one surface 212 and a second through hole 234 formed in the other surface 214 may communicate with each other.

One or more formed via holes 230 are formed in the integrated passive device 210 so that heat that may be generated in the integrated passive device 210 may be discharged through the via holes 230 when the semiconductor package 100 is driven.

The connection of the first bump 220 and the second bump 240 by the via hole 230 allows the heat that may be generated in the integrated passive device 210 to be discharged, so that the efficiency of thermal management of the passive device structure 200 may be improved.

In addition, the capacity of the integrated passive device 210 may be improved by the connection of the first bump 220 and the second bump 240 by the via hole 230.

One or more first bumps 220 may be disposed and formed on one surface 212 at regular intervals or at different intervals. Specifically, the first bump 220 may be disposed at a position in contact with the first through hole 232 of the via hole 230 of the integrated passive device 210, and may be formed in the same number as the formed via holes 230.

Furthermore, the first bump 220 may be formed in a size that fills a gap between the substrate 130 and the integrated passive device 210. That is, the first bump 220 is formed to fill the space between the substrate 130 and the integrated passive device 210 so that the passive device structure 200 may be connected with the substrate 130.

The second bump 240 may be formed on the second through hole 234 of the other surface 214 facing the printed circuit board 110. In addition, the second bumps 240 may be formed to have the same number of via holes 230 formed in the first bumps 220.

In the embodiment, the first through hole 232 and the second through hole 234 communicate with each other, the first bump 220 is formed on the first through hole 232, and the second bump 240 is formed on the second through hole 234, so that the first bump 220 and the second bump 240 may be formed to face each other based on the integrated passive device 210.

As such, when the first bumps 220 and the second bumps 240 are disposed on the upper and lower sides of the integrated passive device 210 and the fluid material for the underfill is introduced to the adhesive layer by maintaining a state in contact with the substrate 130 by the first bumps 220, the integrated passive device 210 is moved by the flow of the fluid material, thereby minimizing the ball grid array 160 from being damaged.

Referring back to the drawings, the ball grid array 160 may be disposed on the adhesive layer 120. As described above, the ball grid array (BGA) 160 is a packaging method that minimizes the problem of increasing the size of the semiconductor when the number of pins of the integrated circuit increases. If the number of pins of the integrated circuit increases, soldering pastes may be connected with each other in a soldering process so that the circuit may be short-circuited, but the ball grid array may prevent the short-circuit of the circuit because a correct amount of soldering is enabled.

The size in which the ball grid array 160 is formed and the size of the passive device structure 200 may be the same as each other or similar to each other. That is, as illustrated in FIG. 4, the ball grid array 160 provided in the adhesive layer 120 may be formed to be fitted between the substrate 130 and the printed circuit board 110. According to such a ball grid array forming structure, the ball grid array 160 formed in the adhesive layer 120 may prevent the ball grid array 160 from being moved by the fluid material in the injection process of the fluid material for the underfill process.

Meanwhile, when the adhesive layer 120 is filled, the stress may change according to a change in the flow of an underfill fluid filled in a suddenly widened space. The ball grid arrays 160 at the edge among the ball grid arrays may be damaged by the changing stress. To minimize the problem, the ball grid array 160 may be formed to have the same or similar size as or to that of the passive device structure 200.

In addition, when the semiconductor device is driven after injecting an underfill fluid material into the adhesive layer 120, shear stress in the ball grid array 160 is generated due to a difference in coefficient of thermal expansion (CTE), so that the ball grid array 160 may be damaged. To minimize this problem, the passive device structure 200 may be formed to have the same or similar size as or to that of the ball grid array 160.

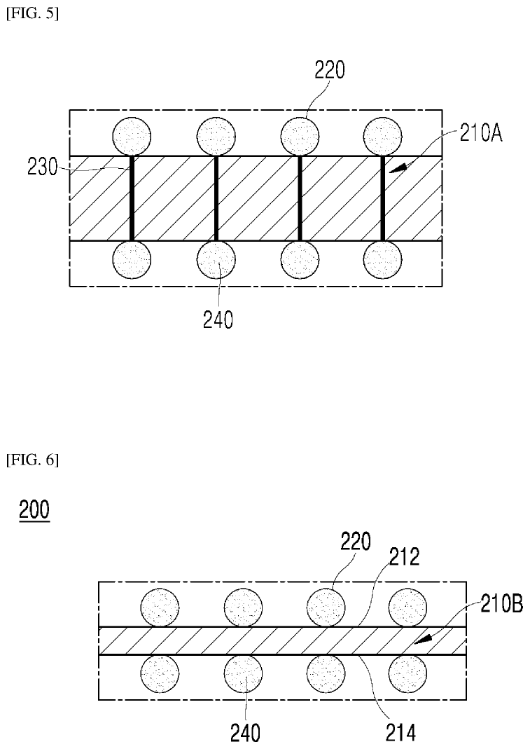

FIG. 4 is a diagram illustrating a first modification embodiment of the passive device structure of the present disclosure, FIG. 5 is a diagram illustrating a second modification embodiment of the passive device structure of the present disclosure, and FIG. 6 is a diagram illustrating a third modification embodiment of the passive device structure of the present disclosure.

Referring to FIG. 4, a passive device structure 200 according to the first modification embodiment may include an integrated passive device 210 including a plurality of via holes 230, first bumps 220 provided on one surface of the integrated passive device 210, and second bumps 240A provided on the other surface of the integrated passive device 210.

The via hole 230 according to the embodiment may be formed to penetrate from one surface 212 of the integrated passive device 210 facing the substrate 130 to the other surface 214 facing the printed circuit board 110. One or more formed via holes 230 are formed in the integrated passive device 210 so that heat that may be generated in the integrated passive device 210 may be discharged through the via holes 230 when the semiconductor package 100 is driven.

One or more first bumps 220 may be disposed and formed on one surface 212 at regular intervals or at different intervals. Specifically, the first bumps 220 may be disposed on the first through hole 232 penetrating through the integrated passive device 210, and may be formed in the same number as the formed first through hole 232.

Further, in the embodiment, the first bump 220 may be formed in a size that fills a gap between the substrate 130 and the integrated passive device 210. That is, the first bump 220 is formed to fill the space between the substrate 130 and the integrated passive device 210 so that the integrated passive device 210 may be connected with the substrate 130. Therefore, when the fluid material for forming the underfill is injected into the adhesive layer 120, it is possible to prevent the integrated passive device 210 from flowing by the fluid material, and to prevent the ball grid array 160 from being damaged by fixing the integrated passive device 210.

Meanwhile, the second bump 240A is formed on the other surface 214 facing the printed circuit board 110, and may be formed to have a size different from that of the first bump 220. In the embodiment, the second bump 240A may be formed to be larger than the first bump 220, and the second bump 240A may be formed at a position misaligned with the second through hole 234.

The second bump 240A is formed on a lower side (the other surface 214) of the integrated passive device 210 to absorb heat generated from the integrated passive device 210. Since the heat generation is minimized, it is possible to prevent damage to the integrated passive device 210 due to heat and a decrease in operation performance due to high temperature.

In the embodiment, the example in which the second bump 240A has a larger size than that of the first bump 220 has been described, but in another embodiment, the second bump 240A may also be formed smaller than the first bump 220.

Referring to FIG. 5, a passive integrated device 210A according to the second modification embodiment may be formed to have a thickness greater than that of the integrated passive device 210 of the embodiment described above.

When comparing the first modification embodiment with the second modification embodiment, the integrated passive device 210 of the first modification embodiment may be formed to have the same thickness as the integrated passive device 210 according to the embodiment of FIG. 3. However, the second bump 240 of the first modification embodiment is formed to be larger than the first bump 220 so that the overall thickness of the passive device structure 200 from the first bump 220 to the second bump 240 is increased.

Similarly, the integrated passive device 210A of the second modification embodiment is formed to be larger than the thickness of the integrated passive device 210 of the first modification embodiment, but the second bump 240 of the second modification embodiment may be formed in the same or similar size as or to the size of the first bump 220. As a result, the overall thickness of the passive device structure 200 may be increased.

In this case, the second bump 240 may be formed on the second through hole 234 of the via hole 230, and in the embodiment, the first bump 220 and the second bump 240 may be positioned to face each other.

In this way, as the overall thickness of the passive device structure 200 increases, the weight of the passive device structure 200 may increase. As a result, it is possible to minimize the passive device structure 200 from being moved in the adhesive layer 120.

In addition, the first bump 220 is formed in the size to fill the space between the substrate 130 and the integrated passive device 210 so that the passive device structure 200 may be fixed to the substrate 130. As a result, when the fluid material for the underfill process is injected into the adhesive layer 120, the ball grid array 160 is formed similarly to the space of the adhesive layer 120 to prevent the ball grid array 160 from being damaged in the adhesive layer 120 due to a change in stress by the underfill fluid flow.

Referring to FIG. 6, the via holes 230 (see FIGS. 4 and 5) may not be formed in an integrated passive device 210B according to the third modification embodiment. As described above, the via hole 230 is a structure for the thermal management efficiency of the passive device structure 200, and the heat generated from the passive device structure 200 is discharged by the second bump 240 to maintain the thermal management efficiency of the integrated passive device 210.

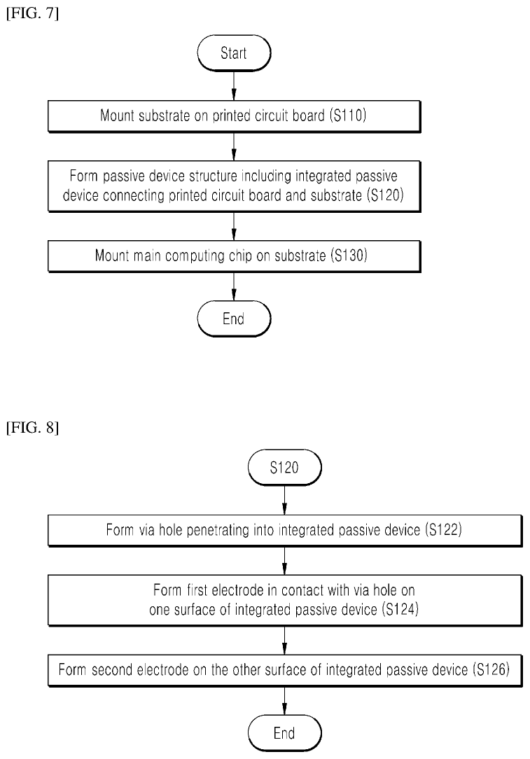

FIGS. 7 and 8 are flowcharts illustrating processes of semiconductor package according to an embodiment of the present disclosure.

Referring to the drawings, in a method for manufacturing a passive device of a semiconductor package according to an embodiment of the present disclosure, first, the substrate 130 may be mounted on the printed circuit board 110 (S110).

Here, the printed circuit board 110 may include a plurality of external bumps, and substrate wirings and internal bumps capable of electrically connecting the semiconductor package.

The substrate 130 mounted on the printed circuit board 110 may be formed with a plurality of wirings that may be electrically connected with the printed circuit board 110.

Meanwhile, a predetermined gap may be formed between the printed circuit board 110 and the substrate 130, and an underfill process may be performed on the formed predetermined gap. In the performed underfill process, a fluid material for the underfill process may be injected, and the adhesive layer 120 may be formed between the printed circuit board 110 and the substrate 130 by the injected fluid material.

When the adhesive layer 120 is formed, the ball grid array 160 for electrically connecting the substrate 130 and the printed circuit board 110 may be formed in the adhesive layer 120. The ball grid array 160 is a packaging method that minimizes a problem of increasing the size of the semiconductor when the number of pins of the integrated circuit increases. If the number of pins of the integrated circuit increases, soldering pastes may be connected with each other in a soldering process so that the circuit may be short-circuited, but the ball grid array is a configuration capable of preventing the short-circuit of the circuit because a correct amount of soldering is enabled.

In addition, when the adhesive layer 120 is formed, the passive device structure 200 including an integrated passive device (IPD) electrically connecting the printed circuit board 110 and the substrate 130 may be formed between the printed circuit board 110 and the substrate 130 (S120).

The passive device structure 200 may be implemented by forming at least one via hole 230 penetrating into the integrated passive device 210 (S122), forming the first bump 220 on one surface 212 of the integrated passive device 210 (S124), and then forming the second bump 240 on the other surface 214 of the integrated passive device 210 (S124).

As described above, the integrated passive device 210 may be an integrated circuit for amplifying power by simultaneously using a power amplifying device and a passive device such as a resistor, a capacitor, and an inductor on a semiconductor substrate.

Heat may be generated in the integrated passive device 210, and a plurality of via holes 230 are formed in the integrated passive device 210, so that the heat generated from the integrated passive device 210 may be discharged through the via holes 230.

The first bump 220 may be formed in a gap formed between the integrated passive device 210 and the substrate 130. That is, the integrated passive device 210 may be electrically connected with the substrate 130 and fixed to the substrate 130 at the same time by the first bump 220.

The second bump 240 is formed on a lower side (the other surface 214) of the integrated passive device 210 to absorb heat generated from the integrated passive device 210. Since the heat generation is minimized, it is possible to prevent damage to the integrated passive device 210 due to heat and a decrease in operation performance due to high temperature.

The first bump 220 may be formed on the via hole 230 at a position in contact with the via hole 230, and the second bump 240 may preferably be formed at a position facing the first bump 220, but may alternatively be formed at any position on the other surface of the integrated passive device 210.

After the passive device structure 200 is formed on the adhesive layer 120, the main computing chip 150 may be mounted on the substrate 130 (S130). Specifically, the main computing chip 150 may be mounted on the upper side of the substrate 130, and may include a plurality of connection terminals 152 that may be electrically connected with the substrate 130.

Meanwhile, the connection terminals 152 may be formed in a size corresponding to the space between the substrate 130 and the main computing chip 150, and may be disposed in an array corresponding to the ball grid array 160 described above.

As described above, the integrated passive device including bumps electrically connectable with the substrate of the semiconductor package may be installed in the semiconductor package according to the embodiment of the present disclosure.

That is, it is possible to prevent a gap from being formed between the substrate and the passive device structure by forming the bumps on one surface in contact with the substrate 130. Accordingly, it is possible to prevent a change in the overall structure of the semiconductor package.

In addition, the integrated passive device including the bumps electrically connectable with the substrate of the semiconductor package is installed to significantly minimize the size of the semiconductor package as compared with the existing passive device structure mounted around the main computing chip on the substrate or on the printed circuit board, and the integrated passive device is disposed at a placed where the electrical signal is moved to pursue the stabilization of the electrical signal and the maximization of energy efficiency.

In addition, the underfill process of the semiconductor package may be performed by filling the fluid material forming the underfill in the space between the substrate and the main computing chip by using a capillary phenomenon. At this time, the integrated passive device maintains the electrical connection between the main computing chip and the substrate by the first bumps formed between the main computing chip and the integrated passive device and the second bumps formed between the substrate and the integrated passive device to prevent the ball grid array in the space where the integrated passive device is mounted from being damaged by the flow of the fluid material forming the underfill.

Furthermore, although the periphery of the integrated passive device is surrounded by the fluid material forming the underfill, thermal flow is enabled by the first bumps formed between the main computing chip and the integrated passive device and the second bumps formed between the substrate and the integrated passive device, thereby preventing the damage to the integrated passive device due to stress by the heat and a decrease in operation performance due to high temperature.

The aforementioned description of the present disclosure is illustrative, and it can be understood to those skilled in the art that the present disclosure can be easily modified in other detailed forms without changing the technical spirit or required features of the present disclosure. Therefore, it should be appreciated that the aforementioned embodiments are illustrative in all aspects and are not restricted. For example, respective components described as single types can be distributed and implemented, and similarly, components described to be distributed can also be implemented in a coupled form.

The scope of the present disclosure is represented by claims to be described below rather than the detailed description, and it is to be interpreted that the meaning and scope of the claims and all the changes or modified forms derived from the equivalents thereof come within the scope of the present disclosure.

What is claimed is:

1. A passive device structure of a semiconductor package comprising:
a substrate mounted on a printed circuit board;
a main computing chip mounted on the substrate; and
a passive device structure which is provided in an adhesive layer formed between the printed circuit board and the substrate and includes an integrated passive device (IPD) electrically connecting the printed circuit board and the substrate,
wherein the passive device structure includes
at least one via hole penetrating into the integrated passive device;
at least one first bump which is formed on one surface facing the substrate of the integrated passive device and in contact with a first through hole of the via hole penetrating through the integrated passive device; and
at least one second bump formed on the other surface facing the printed circuit board of the integrated passive device.

2. The passive device structure of the semiconductor package of claim 1, wherein the first bumps are aligned in a direction parallel to the formation direction of the integrated passive device on one surface facing the printed circuit board of the integrated passive device.

3. The passive device structure of the semiconductor package of claim 1, wherein the second bump is in contact with a second through hole of the via hole penetrating through the integrated passive device.

4. The passive device structure of the semiconductor package of claim 1, wherein the second bumps are aligned in a direction parallel to the formation direction of the integrated passive device on the other surface facing the substrate of the integrated passive device.

5. The passive device structure of the semiconductor package of claim 1, wherein the sizes of the first bump and the second bump are different from each other.

6. The passive device structure of the semiconductor package of claim 5, wherein a diameter of the second bump is larger than the diameter of the first bump.

7. The passive device structure of the semiconductor package of claim 1, further comprising:
a ball grid array (B GA) disposed between the printed circuit board and the substrate,
wherein a thickness of the passive device structure is formed to be equal to or smaller than the ball grid array.

8. A method for manufacturing a passive device structure of a semiconductor package comprising steps of:
mounting a substrate on a printed circuit board;
forming a passive device structure including an integrated passive device (IPD) electrically connecting the printed circuit board and the substrate; and
mounting a main computing chip on the substrate,
wherein the forming step comprises
forming at least one via hole penetrating into the integrated passive device;
forming at least one first bump which is formed on one surface facing the printed circuit board of the integrated passive device and in contact with a first through hole of the via hole penetrating through the integrated passive device; and
forming at least one second bump formed on the other surface facing the substrate of the integrated passive device.

9. The method for manufacturing the passive device structure of the semiconductor package of claim 8, wherein the forming of the second bumps includes forming the second bumps to be in contact with a second through hole of the via hole penetrating through the integrated passive device.

10. The method for manufacturing the passive device structure of the semiconductor package of claim 8, wherein the forming step includes forming the first bumps and the second bumps having different sizes.

11. The method for manufacturing the passive device structure of the semiconductor package of claim 10, wherein the forming of the second bump includes forming the second bump larger than the diameter of the first bump.

12. The method for manufacturing the passive device structure of the semiconductor package of claim 8, further comprising:
forming a ball grid array (BGA) disposed between the printed circuit board and the substrate,
wherein the forming step is forming to be equal to or smaller than the ball grid array.
